(19) United States
(12) Patent Application Publication
(10) Pub. No.: US 2013/0135835 A1
(43) Pub. Date: May 30, 2013

(54) PRINTED CIRCUIT BOARD CAPABLE OF DECREASING ELECTROMAGNETIC INTERFERENCE

(71) Applicants: HSIN-HUNG LIU, Tu-Cheng (TW); SHU-WEI CHANG, Tu-Cheng (TW); FU-HSIUNG YANG, Tu-Cheng (TW)

(72) Inventors: HSIN-HUNG LIU, Tu-Cheng (TW); SHU-WEI CHANG, Tu-Cheng (TW); FU-HSIUNG YANG, Tu-Cheng (TW)

(73) Assignee: HON HAI PRECISION INDUSTRY CO., LTD., Tu-Cheng (TW)

(21) Appl. No.: 13/330,709

(22) Filed: Dec. 20, 2011

(30) Foreign Application Priority Data
Nov. 24, 2011 (TW) 100143076

(51) Int. Cl. H05K 7/06

(52) U.S. Cl. 361/782

(57) ABSTRACT

A printed circuit board includes an antenna, an EMI source, and inductor. The EMI source is connected to the printed circuit board by a pin. The inductor is connected between the pin and a ground of the printed circuit board. The connected inductor increases the resonant frequency of the EMI source to make the resonant frequency of EMI source away from the antenna. Thereby the EMI generated by the EMI source is decreased and the radiation efficiency of the antenna increases.

### BACKGROUND

1. Technical Field

The present disclosure relates to printed circuit boards capable of decreasing electromagnetic interference and, particularly, to a printed circuit board capable of decreasing electromagnetic interference generated by components around an antenna fixed on the printed circuit board.

2. Description of Related Art

Components in electronic device are arranged compactly to save space of the electronic device. Generally, a camera and earphone jacks are arranged near an antenna. The camera and earphone include electromagnetic interference (EMI) source, such as metal. When resonant frequencies of the antenna and the EMI source are approximate, the EMI is generated which impacts radiation efficiency of the antenna.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a schematic view of a printed circuit board in accordance with an exemplary embodiment.

FIG. 2 is a radiation loss diagram of a GPS antenna when an inductor is not connected to the printed circuit board of FIG. 1.

FIG. 3 is a radiation loss diagram of a GPS antenna when the inductor is connected to the printed circuit board of FIG. 1.

### DETAILED DESCRIPTION

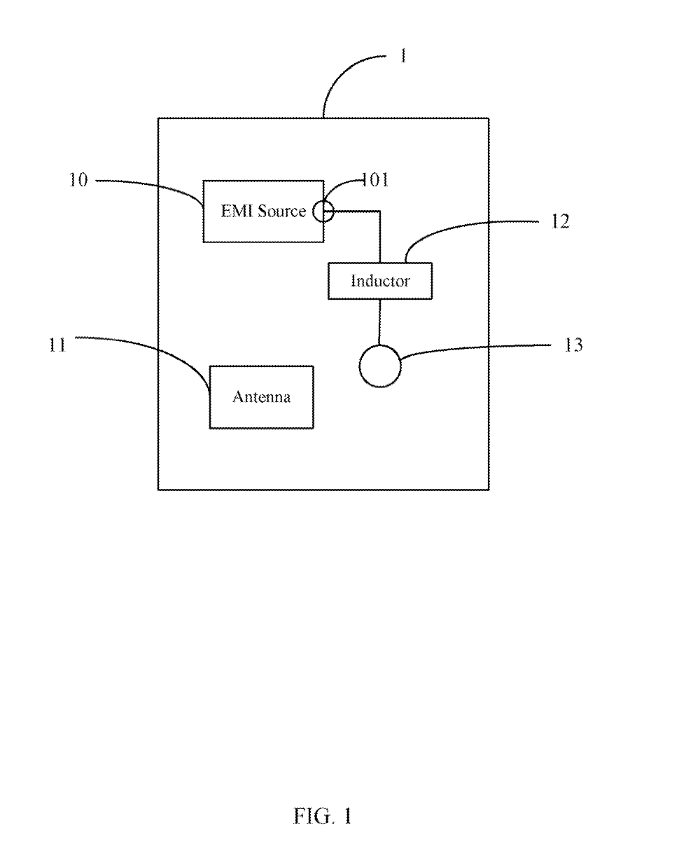

Referring to FIG. 1, a printed circuit board (PCB) 1 placed inside an electronic device (not shown) includes an antenna 11 and an EMI source 10. The resonant frequencies of the antenna 11 and the EMI source 10 are approximate. The EMI source 10 is connected to the PCB 1 by a pin 101. An inductor 12 is connected between the pin 101 and a ground 13 of the PCB 1. The connected inductor 12 is configured to increase the resonant frequency of the EMI source 10 so as to make the resonant frequency of EMI source 10 away from the antenna 11. Accordingly, the EMI generated by the EMI source 10 is decreased and the radiation efficiency of the antenna 11 is recovered. In the embodiment, the EMI source 10 is component covered by a piece of metal and near the antenna 11.

In the embodiment, the antenna 11 is a GPS antenna whose frequency band is 1.575 GHZ. The inductance value of the inductor 12 is in a range from 12 nH to 82 nH. The inductance value of the inductor 12 is inversely proportional to the resonant frequency of the EMI source 10.

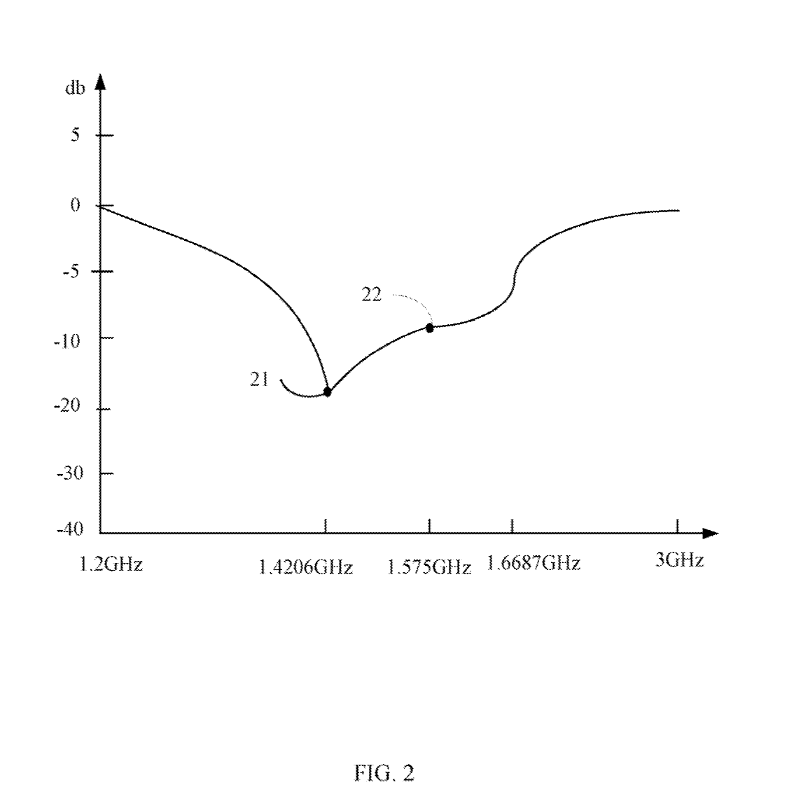

FIG. 2 is a radiation loss diagram of the GPS antenna when the inductor 12 is not connected to the PCB 1. If being not interfered by the EMI, the GPS antenna 11 resonates at a second position 22 whose frequency is 1.575 GHz. However, due to the EMI generated by the EMI source 10, the GPS antenna resonates at a first position 21 whose frequency is 1.4206 GHz.

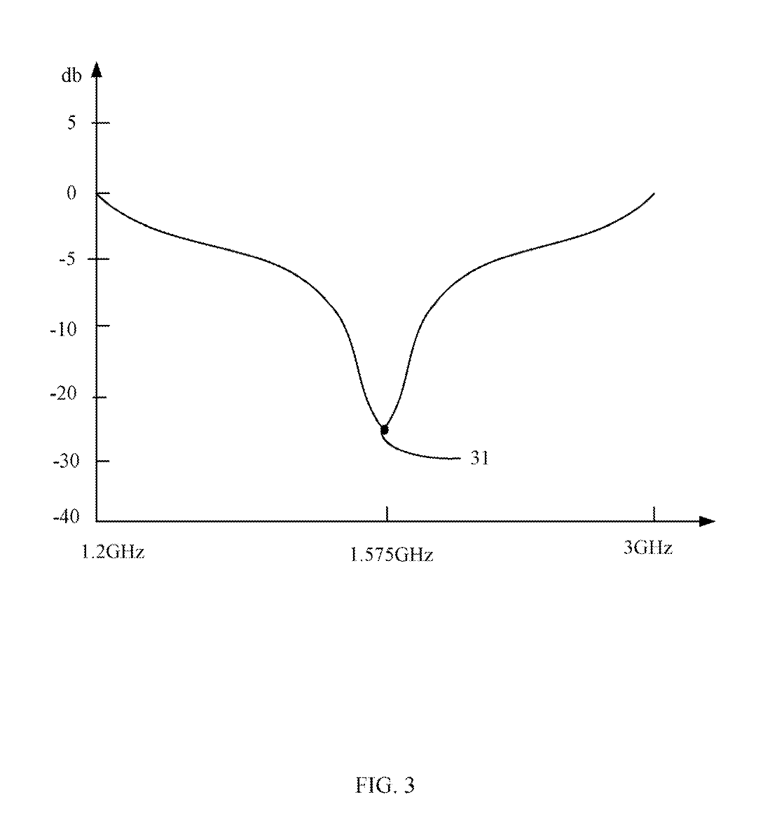

FIG. 3 is a radiation loss diagram of the GPS antenna when the inductor 12 is connected to the PCB 1. As shown in FIG. 3, the GPS antenna 11 resonates at a third position 31 whose frequency is 1.575 GHz, namely, the resonation frequency of the GPS antenna 11 is recovered when the inductor 12 is connected to the PCB 1.

Further, as shown in FIG. 2, when the inductor 12 is not connected to the PCB 1, the radiation loss of the first position 21 is −15.408 dB, and when the inductor 12 is connected to the PCB 1, the radiation loss of the fourth position 31 is decreased to −25.902 dB, namely the radiation efficiency of the GPS antenna 11 is increased when the inductor 12 is connected to the PCB 1.

Although the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. A printed circuit board comprising:
an antenna;
an electromagnetic interference (EMI) source connected to the printed circuit board by a pin; and
an inductor connected between the pin and a ground of the printed circuit board.

2. The printed circuit board as described in claim 1, wherein the EMI source is a component covered by a piece of metal and near the antenna.

3. The printed circuit board as described in claim 1, wherein the antenna is a GPS antenna whose frequency band is 1.575 GHZ.

4. The printed circuit board as described in claim 1, wherein the inductance value of the inductor is in a range from 12 nH to 82 nH.

5. The printed circuit board as described in claim 1, wherein the inductance value of the inductor is inversely proportional to a resonant frequency of the EMI source.
